(19) United States
(12) Patent Application Publication
(10) Pub. No.: US 2015/0075599 A1
(43) Pub. Date: Mar. 19, 2015

(54) PILLAR STRUCTURED MULTIJUNCTION PHOTOVOLTAIC DEVICES

(71) Applicant: ZENA TECHNOLOGIES, INC., Cambridge, MA (US)

(72) Inventors: Young-June YU, Cranbury, NJ (US); Munib WOBER, Topsfield, MA (US)

(73) Assignee: ZENA TECHNOLOGIES, INC., Cambridge, MA (US)

(21) Appl. No.: 14/032,166

(22) Filed: Sep. 19, 2013

(51) Int. Cl. H01L 31/0236; H01L 31/18

(52) U.S. Cl. CPC H01L 31/02363; H01L 31/1876
USPC 136/256; 438/81

(57) ABSTRACT

A device operable to convert light to electricity, comprising: a substrate comprising a semiconductor material, one or more structures essentially perpendicular to the substrate, one or more layers conformally disposed on the one or more structures wherein the one or more structures and the one or more layers form one or more junctions, and an electrically conductive material disposed on the substrate in the area between the one or more structures.

### CROSS-REFERENCE TO RELATED APPLICATIONS

This application is related to U.S. patent application Ser. Nos. 12/621,497, 12/633,297, 61/266064, 12/982269, 12/966573, 12/967880, 61/357429, 12/974499, 61/360421, 12/910664, 12/945492, 12/966514, 12/966535, 13/047392, 13/048635, 13/106851, 61/488535, 13/288131, 13/494661, and 13/543307, the disclosures of which are hereby incorporated by reference in their entirety.

### BACKGROUND

A photovoltaic device, also called a solar cell is a solid state device that converts the energy of sunlight directly into electricity by the photovoltaic effect. Assemblies of cells are used to make solar modules, also known as solar panels. The energy generated from these solar modules, referred to as solar power, is an example of solar energy.

The photovoltaic effect is the creation of a voltage (or a corresponding electric current) in a material upon exposure to light. Though the photovoltaic effect is directly related to the photoelectric effect, the two processes are different and should be distinguished. In the photoelectric effect, electrons are ejected from a material's surface upon exposure to radiation of sufficient energy. The photovoltaic effect is different in that the generated electrons are transferred between different bands (i.e. from the valence to conduction bands) within the material, resulting in the buildup of a voltage between two electrodes.

Photovoltaics is a method for generating electric power by using solar cells to convert energy from the sun into electricity. The photovoltaic effect refers to photons of light—packets of solar energy—bumping electrons into a higher state of energy to create electricity. At higher state of energy, the electron is able to escape from its normal position associated with a single atom in the semiconductor to become part of the current in an electrical circuit. These photons contain different amounts of energy that correspond to the different wavelengths of the solar spectrum. When photons strike a photovoltaic cell, they may be reflected or absorbed, or they may pass right through. The absorbed photons can generate electricity. The term photovoltaic denotes the unbiased operating mode of a photodiode in which current through the device is entirely due to the light energy. Virtually all photovoltaic devices are some type of photodiode.

### SUMMARY

Described herein is a device operable to convert light to electricity, comprising a substrate comprising a semiconductor material having a first side and a second side, one or more structures essentially perpendicular to the first side of the substrate, one or more layers conformally disposed on the one or more structures wherein the one or more structures and the one or more layers form one or more junctions, and an electrically conductive material disposed on the first side of the substrate in an area between the one or more structures. The one or more layers are epitaxial or amorphous.

### BRIEF DESCRIPTION OF THE DRAWINGS

FIG. 1A is a schematic cross sectional view of a coaxial double junction pillar structured photovoltaic device according to an embodiment.

FIG. 1B shows details of the device of FIG. 1A.

FIG. 1C shows details of the one or more junctions of FIGS. 1A and 1B.

FIG. 2A is a schematic cross sectional view of a coaxial triple junction pillar structured photovoltaic device according to an embodiment.

FIG. 2B shows details of the device of FIG. 2A.

FIG. 2C shows details of the one or more junctions of FIGS. 2A and 2B.

FIG. 3A is a schematic cross sectional view of a coaxial quadruple junction pillar structured photovoltaic device according to an embodiment.

FIG. 3B shows details of the device of FIG. 3A.

FIG. 3C shows details of the one or more junctions of FIGS. 3A and 3B.

FIGS. 4A-4C are schematic cross sectional views of a bifacial pillar structured photovoltaic device according to an embodiment.

FIG. 5 is an exemplary process of manufacturing the photovoltaic device of FIGS. 1A, 1B, and 1C according to an embodiment.

FIG. 6 is a schematic cross sectional view of a coaxial triple junction tapered pillar structured photovoltaic device according to an embodiment.

FIG. 7 is an exemplary process of manufacturing the photovoltaic device of FIG. 6 according to an embodiment.

FIG. 8 shows alternative stripe-shaped structures of the photovoltaic device according to an embodiment.

FIG. 9 shows alternative mesh-shaped structures of the photovoltaic device according to an embodiment.

### DETAILED DESCRIPTION OF THE INVENTION

The term “photovoltaic device” as used herein means a device that can generate electrical power by converting light such as solar radiation into electricity. The term “single-crystal” as used herein means that the crystal lattice of the material is continuous and unbroken throughout the entire structures, with essentially no grain boundaries therein. An electrically conductive material can be a material with essentially zero band gap. The electrical conductivity of an electrically conductive material is generally above 10³ S/cm. A semiconductor can be a material with a finite band gap up to about 3 eV and generally has an electrical conductivity in the range of 10³ to 10⁸S/cm. An electrically insulating material can be a material with a band gap greater than about 3 eV and generally has an electrical conductivity below 10⁻⁸ S/cm. The term “structures essentially perpendicular to the substrate” as used herein means that angles between the structures and the substrate are from 85° to 90°. The term “cladding layer” as used herein means a layer of substance surrounding the structures. The term “intrinsic layer” as used herein means an undoped semiconductor layer. The term “inter layer” as used herein means a layer of substance sandwiched between two other layers. The term “continuous” as used herein means having no gaps, holes, or breaks. The term “coupling layer” as used herein means a layer effective to guide light into the structures.

A group III-V compound material, as used herein, means a compound consisting of a group III element and a group V element. A group III element can be B, Al, Ga, In, Tl, Sc, Y, the lanthanide series of elements or the actinide series of elements. A group V element can be V, Nb, Ta, Db, N, P, As, Sb or Bi. A group II-VI compound material, as used herein, means a compound consisting of a group II element and a group VI element. A group II element can be Be, Mg, Ca, Sr, Ba or Ra. A group VI element can be Cr, Mo, W, Sg, O, S, Se, Te, or Po. A quaternary material is a compound consisting of four elements.

A device, comprising: a substrate comprising a semiconductor material having a first side and a second side, one or more structures essentially perpendicular to the first side of the substrate, one or more layers conformally disposed on the one or more structures wherein the one or more structures and the one or more layers form one or more junctions, and an electrically conductive material disposed on the first side of the substrate in an area between the one or more structures. The photovoltaic device preferably comprises at least two junctions conformally disposed on the one or more structures.

In an embodiment, the substrate is a single crystalline electrically conductive material. The substrate can comprise one or more metals, one or more other electrically conductive materials, or a combination thereof.

In an embodiment, the substrate has a thickness of about 5 μm to about 300 μm, preferably of about 100 μm.

In an embodiment, the one or more structures essentially perpendicular to the substrate are cylinders or prisms with a cross-section selected from a group consisting of elliptical, circular, rectangular, and polygonal cross-sections, strips. The one or more structures essentially perpendicular to the substrate may be a mesh. The term “mesh” as used herein means a web-like pattern or construction.

In an embodiment, the structures are cylinders with diameters from about 0.2 μm to about 10 μm, preferably with diameters about 1 μm.

In an embodiment, the structures are cylinders, prisms, cones, frusta and/or pyramids with heights from about 2 μm to about 50 μm, preferably about 10 μm; a center-to-center distance between two closest structures is about 0.5 μm to about 20 μm, preferably about 2 μm. The term “pyramids” as used herein means a polyhedron formed by connecting a polygonal base (not limited to a rectangular base) and a point, called the apex.

In an embodiment, the structures are of the same composition as the substrate. In an embodiment, the structures and the substrate form a single crystal. In an embodiment, the structures are an electrically conductive material comprising one or more metals, one or more other electrically conductive materials, or a combination thereof.

In an embodiment, a top portion of the structures is rounded or tapered. The structures may be rounded or tapered by any suitable method such as isotropic etch. The rounded or tapered top portion can enhance light coupling to the structures.

In an embodiment, an intrinsic layer is disposed on the structures. In an embodiment, this intrinsic layer is coextensive with the entire interface of the structures. This intrinsic layer may have a thickness of about 1 nm to about 20 nm, preferably about 4 nm. This intrinsic layer may be transparent, and can be made of an amorphous silicon material. This intrinsic layer can reduce any dark current and forms a coaxial p-i-n junction with other layers on the structures.

In an embodiment, a first doped layer is disposed on the intrinsic layer. In an embodiment, this first doped layer is coextensive with the entire interface of the intrinsic layer. The first doped layer can be made of amorphous silicon. The first doped layer can be p doped (p+) or n doped (n+), preferably p doped (p+). In an embodiment, the first doped layer has a thickness of about 2 nm to about 50 nm, preferably about 10 nm. The first doped layer forms a first junction with the structures.

In an embodiment, one or more additional layers are conformally disposed on the first junction formed with the structures. These one or more additional layers form one or more additional junctions (e.g., 2^{nd} junction, 3^{rd} junction and 4^{th} junction in Table 1). The first junction and the one or more additional junctions may be selected from a p-i-n junction, a p-n junction, a heterojunction, or a combination thereof. In an embodiment, each of these junctions has a thickness of about 5 nm to about 100 nm, preferably about 20 nm.

In an embodiment, one of the junctions comprises a doped p type (p+) semiconductor material layer, a lightly doped (n−) semiconductor material layer, and a doped n type (n+) semiconductor material layer. The p+ layer, the n− layer, and the n+ layer form a p-n junction or heterojunction. The p+ layer, the n− layer, and the n+ layer may be different semiconductor materials or the same semiconductor materials. The p+ layer, the n− layer, and the n+ layer may be single crystalline, epitaxial, polycrystalline or amorphous.

In an embodiment, one of the junctions comprises a doped p type (p+) semiconductor material layer, a lightly doped (p−) semiconductor material layer, and a doped n type (n+) semiconductor material layer. The p+ layer, the p− layer, and the n+ layer form a p-n junction or heterojunction. The p+ layer, the p− layer, and the n+ layer may be different semiconductor materials or the same semiconductor materials. The p+ layer, the p− layer, and the n+ layer may be single crystalline, epitaxial, polycrystalline or amorphous.

In an embodiment, one of the junctions comprises a doped p type (p+) semiconductor material layer, an intrinsic (i) semiconductor layer and a doped n type (n+) semiconductor material layer. The p+ layer, i layer, and the n+ layer form a p-i-n junction. The p+ layer, i layer, and the n+ layer may be single crystalline, epitaxial, polycrystalline (interchangeably referred to as “multicrystalline”), microcrystalline (“μc”) (interchangeably referred to as “nanocrystalline” or “nc”) or amorphous. In an embodiment, the junctions comprise one or more semiconductor materials selected from a group consisting of silicon, germanium, group III-V compound materials, group II-VI compound materials, and quaternary materials.

In an embodiment, an inter layer may be disposed between the first doped layer and the junctions. The inter layer may be coextensive with the entire interface between the first doped layer and the junctions. In an embodiment, the inter layer is also disposed between each pair of junctions. The inter layer is coextensive with the entire interface between a pair of neighboring junctions. In an embodiment, the inter layer comprises an electrically transparent conductive oxide material selected from a group consisting of ITO (indium tin oxide), AZO (aluminum doped zinc oxide), ZIO (zinc indium oxide), ZTO (zinc tin oxide), and a combination thereof. The inter layer may have a thickness of about 2 nm to about 50 nm, preferably about 10 nm. This inter layer preferably has a transmittance of at least 90% for visible light. This inter layer preferably forms an Ohmic contact with the pair of neighboring junctions. The inter layer preferably is effective to prevent diffusion between the neighboring junctions.

Nanocrystalline semiconductor, also known as microcrystalline semiconductor, is a form of porous semiconductor. It is an allotropic form of semiconductor with paracrystalline structure—is similar to amorphous semiconductor, in that it has an amorphous phase. Nanocrystalline semiconductor differs from amorphous semiconductor in that a nanocrystalline semiconductor has small crystalline grains within the amorphous phase. This is in contrast to polycrystalline semiconductor (e.g., poly-Si) which consists solely of crystalline grains, separated by grain boundaries.

In an embodiment, the band gap of an inner junction (i.e., a junction closer to the structures) is smaller than the band gap of an outer junction (i.e., a junction farther from the structures).

Table 1 shows exemplary materials and combinations of the junctions.

| | | | | 4^{th} junction |
|---|---|---|---|---|
| | | | | (conformally |
| | | 2^{nd} junction | 3^{rd} junction | disposed on |
| | 1^{st} junction (the | (conformally | (conformally | the 3^{rd} |
| | first doped layer | disposed on | disposed | junction and |
| | disposed on the | the 1^{st} | on the 2^{nd} | farthest from |
| | structures) | junction) | junction) | the structures) |
| Two | P+ a-Si/i a-Si/c-Si | a-Si p-i-n | none | none |
| junctions | or | junction | | |
| on the | c-Si p-i-n | | | |
| structures | or | | | |
| | P+ a-Ge/i a-Ge/ | | | |
| | c-Ge | | | |
| | or | | | |
| | c-Ge p-i-n | | | |
| | where the | | | |
| | structures | | | |
| | comprise c-Si or | | | |
| | c-Ge materials | | | |
| Three | P+ a-Si/i a-Si/c-Si | a-SiGe p-i-n | a-Si p-i-n | none |
| junctions | or | junction | junction | |
| on the | c-Si p-i-n | or | or | |
| structures | or | μc Si p-i-n | InGaP | |
| | P+ a-Ge/i a-Ge/ | junction | | |
| | c-Ge | or | | |
| | or | InGaAs | | |
| | c-Ge p-i-n | | | |
| | where the | | | |
| | structures | | | |
| | comprise c-Si or | | | |
| | c-Ge materials | | | |
| Four | P+ a-Ge/i a-Ge/ | μc-Si p-i-n | a-SiGe p-i-n | a-Si p-i-n |
| junctions | c-Ge | junction | junction | junction |
| on the | or | or | or | or |
| structures | c-Ge p-i-n | InGaAs | InAlGaAs | InAlGaP |
| | where the | | | |
| | structures | | | |
| | comprise c-Ge | | | |
| | materials | | | |

In an embodiment, a cladding layer may be disposed conformally on the outermost junction (i.e., the junction that is among those junctions conformally disposed on the structures and is not between another junction and the structures). A transparent inter layer may be disposed between the outermost junction and the cladding layer.

The cladding layer is substantially transparent to visible light with a transmittance of at least 50%. The cladding layer may be made of an electrically conductive material. In an embodiment, the cladding layer is a transparent conductive oxide material selected from a group consisting of indium tin oxide, aluminum doped zinc oxide, zinc indium oxide, and zinc tin oxide. The cladding layer may consist of two layers, a thin transparent conductive oxide layer and a thick dielectric oxide layer. In an embodiment, the thin conductive cladding layer the cladding layer is a material selected from a group consisting of indium tin oxide, aluminum doped zinc oxide, zinc indium oxide, and zinc tin oxide. In an embodiment, the thick dielectric cladding layer is a material selected from a group consisting of Si₃N₄, Al₂O₃, and HfO₂. In an embodiment, the cladding layer has a refractive index of about 2. In an embodiment, the cladding layer has a refractive index lower than that of any junctions between the cladding layer and the structures. In an embodiment, the cladding layer has a thickness from about 10 nm to about 500 nm, preferably about 200 nm. In an embodiment, the cladding layer is configured as an electrode of the photovoltaic device.

According to an embodiment, an electrically conductive material is disposed on the substrate in the area between the structures. The side walls of the structures are essentially free of the electrically conductive material. The electrically conductive material may be a material selected from a group consisting of Al, Ti, Ni, Cr, Cu, Ag, Pd, Pt, and a combination thereof. The reflective layer preferably has a reflectance (i.e., the fraction of incident electromagnetic power that is reflected) of at least 50% for visible light (i.e., light have a wavelength from 390 to 750 nm) of any wavelength. The electrically conductive material has a thickness of about 5 nm to about 200 nm, preferably about 80 nm. The electrically conductive material in the area between the structures is preferably connected. The electrically conductive material is functional to reflect light incident thereon to the structures so that the light is absorbed by the structures; and/or the electrically conductive material is functional as an electrode of the photovoltaic device. The electrically conductive material is preferably non-planar. The term “electrode” as used herein means a conductor used to establish electrical contact with the photovoltaic device.

In an embodiment, space between the structures may be filled with a filler material such as a polymer. The filler material preferably is transparent and/or has a low refractive index. In an embodiment, a top surface of the filler material comprises one or more microlenses configured to concentrate incident light on the photovoltaic device onto the structures.

In an embodiment, a second doped layer is disposed on the face of the substrate opposite to the face comprising the one or more structures. The second doped layer can be n doped (n+) or p doped (p+), preferably n doped (n+).

In an embodiment, a passivation layer is disposed on the second doped layer, wherein the passivation layer is configured to passivate the second doped layer. The passivation layer can be removed partially to create openings in the passivation layer. The passivation layer is made of an oxide material selected from a group consisting of Al₂O₃, HfO₂, SiO₂, and a combination thereof. The passivation layer is deposited to reduce surface recombination.

In an embodiment, a metal layer is disposed on the passivation layer and the openings of the passivation layer. The metal layer is made of material selected from a group consisting of Al, Tl, Cr, Cu, Ag, Pd, Pt, and a combination thereof. The metal layer in the openings of the passivation layer creates localized ohmic contacts with the second doped layer; and/or the metal layer is functional as an electrode of the photovoltaic device.

In an embodiment, a first structure of one or more structures and a second structure of one or more structures are on opposite sides of the substrate. The number of junctions and layers on each of the structures on the first structure of one or more structures does not have to be identical to the number of junctions and layers on each of the structures of the second structure of one or more structures.

In an embodiment, a method of making the photovoltaic device comprises: generating a pattern of openings in a resist layer using a lithography technique, wherein locations and shapes of the openings correspond to location and shapes of the structures; forming the structures and regions therebetween by etching the substrate; depositing the reflective layer to the bottom wall. A resist layer as used herein means a thin layer used to transfer a pattern to the substrate, which the resist layer is deposited upon. A resist layer can be patterned via lithography to form a (sub)micrometer-scale, temporary mask that protects selected areas of the underlying substrate during subsequent processing steps. The resist is generally proprietary mixtures of a polymer or its precursor and other small molecules (e.g. photoacid generators) that have been specially formulated for a given lithography technology. Resists used during photolithography are called photoresists. Resists used during e-beam lithography are called e-beam resists. A lithography technique can be photolithography, e-beam lithography, holographic lithography. Photolithography is a process used in microfabrication to selectively remove parts of a thin film or the bulk of a substrate. It uses light to transfer a geometric pattern from a photo mask to a light-sensitive chemical photo resist, or simply “resist,” on the substrate. A series of chemical treatments then engraves the exposure pattern into the material underneath the photo resist. In complex integrated circuits, for example a modern CMOS, a wafer will go through the photolithographic cycle up to 50 times. E-beam lithography is the practice of scanning a beam of electrons in a patterned fashion across a surface covered with a film (called the resist), (“exposing” the resist) and of selectively removing either exposed or non-exposed regions of the resist (“developing”). The purpose, as with photolithography, is to create very small structures in the resist that can subsequently be transferred to the substrate material, often by etching. It was developed for manufacturing integrated circuits, and is also used for creating nanotechnology artifacts.

In an embodiment, the structures and regions therebetween are formed by deep etch followed by isotropic etch. A deep etch is a highly anisotropic etch process used to create deep, steep-sided holes and trenches in wafers, with aspect ratios of often 20:1 or more. An exemplary deep etch is the Bosch process. The Bosch process, also known as pulsed or time-multiplexed etching, alternates repeatedly between two modes to achieve nearly vertical structures: 1. a standard, nearly isotropic plasma etch, wherein the plasma contains some ions, which attack the wafer from a nearly vertical direction (For silicon, this often uses sulfur hexafluoride (SF₆)); 2. deposition of a chemically inert passivation layer (for instance, C₄F₈ source gas yields a substance similar to Teflon). Each phase lasts for several seconds. The passivation layer protects the entire substrate from further chemical attack and prevents further etching. However, during the etching phase, the directional ions that bombard the substrate attack the passivation layer at the bottom of the trench (but not along the sides). They collide with it and sputter it off, exposing the substrate to the chemical etchant. These etch/deposit steps are repeated many times over resulting in a large number of very small isotropic etch steps taking place only at the bottom of the etched pits. To etch through a 0.5 mm silicon wafer, for example, 100-1000 etch/deposit steps are needed. The two-phase process causes the sidewalls to undulate with an amplitude of about 100-500 nm. The cycle time can be adjusted: short cycles yield smoother walls, and long cycles yield a higher etch rate. Isotropic etch is non-directional removal of material from a substrate via a chemical process using an etchant substance. The etchant may be a corrosive liquid or a chemically active ionized gas, known as a plasma.

In an embodiment, a method of converting light to electricity comprises: exposing the photovoltaic device to light; drawing an electrical current from the photovoltaic device. The electrical current can be drawn from the wavelength-selective layer.

In an embodiment, a photo detector comprises the photovoltaic device, wherein the photo detector is configured to output an electrical signal when exposed to light.

In an embodiment, a method of detecting light comprises exposing the photovoltaic device to light; measuring an electrical signal from the photovoltaic device. The electrical signal can be an electrical current, an electrical voltage, an electrical conductance and/or an electrical resistance. A bias voltage is applied to the structures in the photovoltaic device.

In an embodiment, photovoltaic devices produce direct current electricity from sunlight, which can be used to power equipment or to recharge a battery. A practical application of photovoltaics was to power orbiting satellites and other spacecraft, but today the majority of photovoltaic modules are used for grid connected power generation. In this case an inverter is required to convert the DC to AC. There is a smaller market for off-grid power for remote dwellings, boats, recreational vehicles, electric cars, roadside emergency telephones, remote sensing, and cathodic protection of pipelines. In most photovoltaic applications, the radiation is sunlight and for this reason the devices are known as solar cells. In the case of a p-n junction solar cell, illumination of the material results in the creation of an electric current as excited electrons and the remaining holes are forced to move in different directions by the built-in electric field of the depletion region and by diffusion. Solar cells are often electrically connected and encapsulated as a module. Photovoltaic modules often have a sheet of glass on the front (sun up) side, allowing light to pass while protecting the semiconductor wafers from the elements (rain, hail, etc.). Solar cells are also usually connected in series in modules, creating an additive voltage. Connecting cells in parallel will yield a higher current. Modules are then interconnected, in series or parallel, or both, to create an array with the desired peak DC voltage and current.

In an embodiment, the photovoltaic device can also be associated with buildings: either integrated into them, mounted on them or mounted nearby on the ground. The photovoltaic device can be retrofitted into existing buildings, usually mounted on top of the existing roof structure or on the existing walls. Alternatively, the photovoltaic device can be located separately from the building but connected by cable to supply power for the building. The photovoltaic device can be used as a principal or ancillary source of electrical power. The photovoltaic device can be incorporated into the roof or walls of a building.

In an embodiment, the photovoltaic device can also be used for space applications such as in satellites, spacecrafts, space stations, etc. The photovoltaic device can be used as main or auxiliary power sources for land vehicles, marine vehicles (boats) and trains. Other applications include road signs, surveillance cameras, parking meters, personal mobile electronics (e.g., cell phones, smart phones, laptop computers, personal media players).

### EXAMPLES

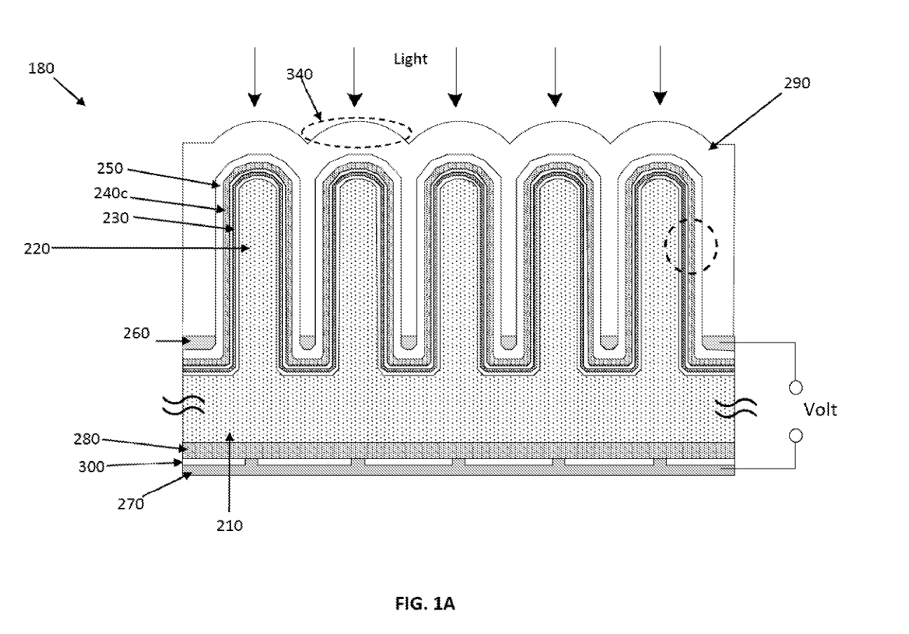

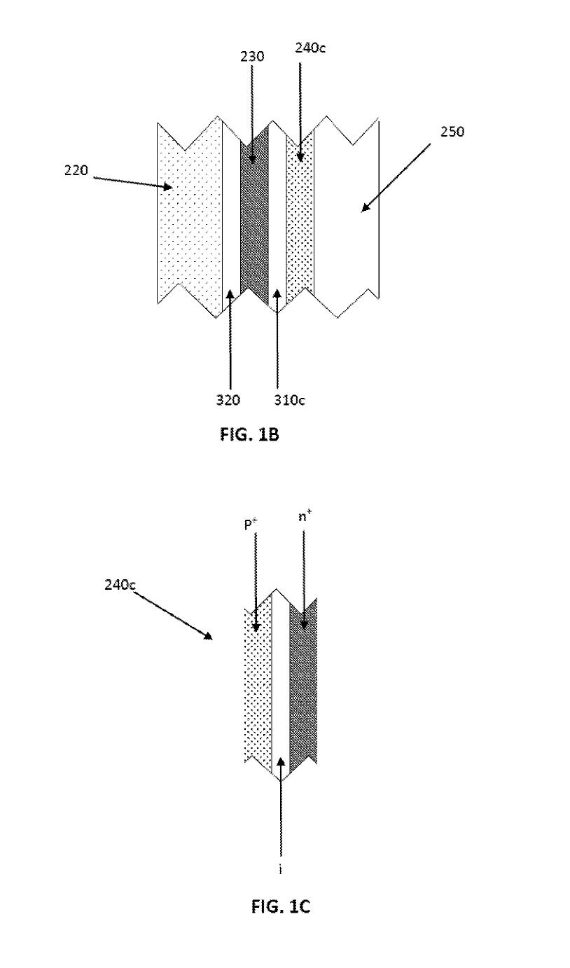

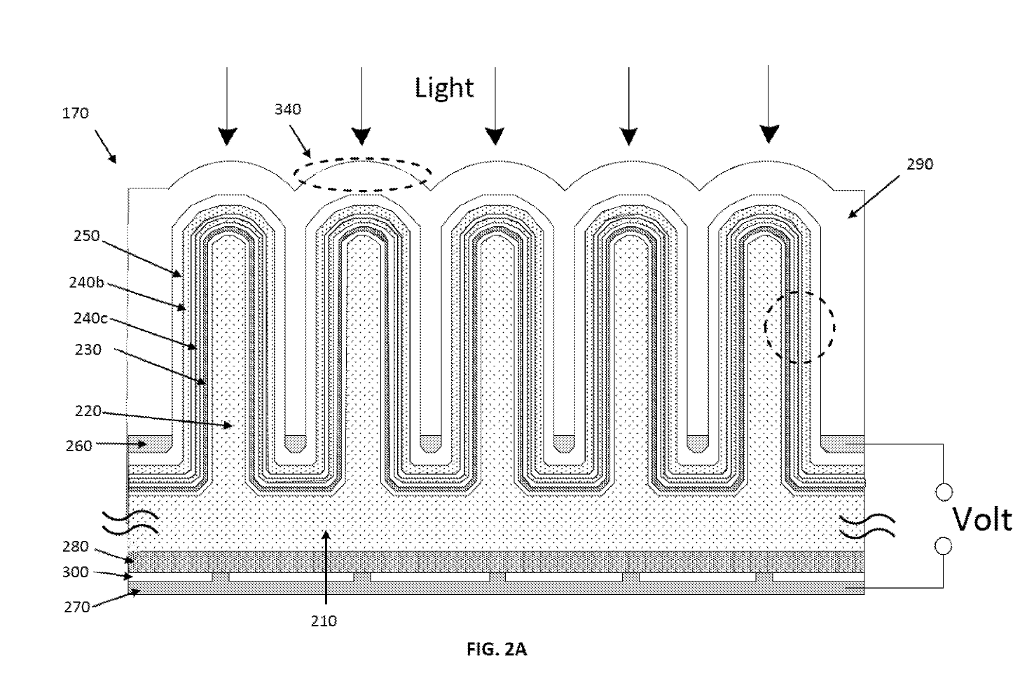

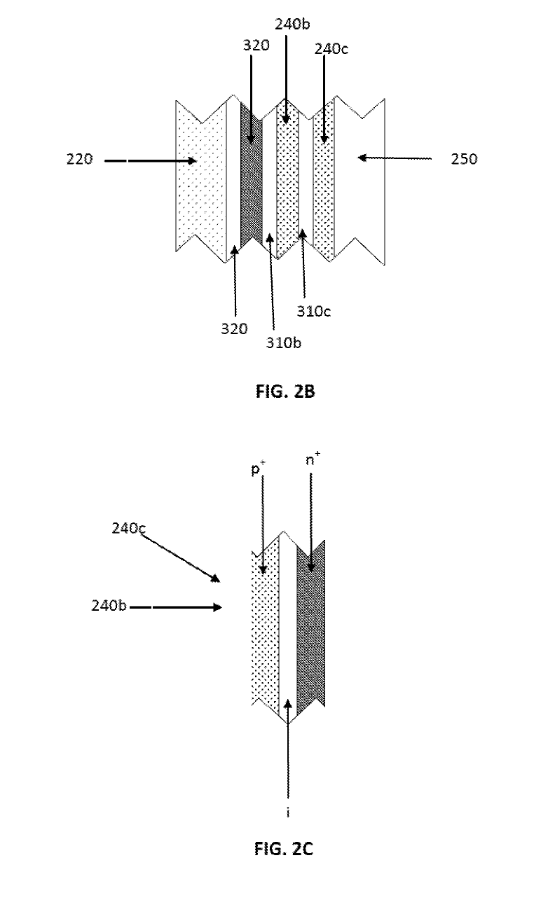

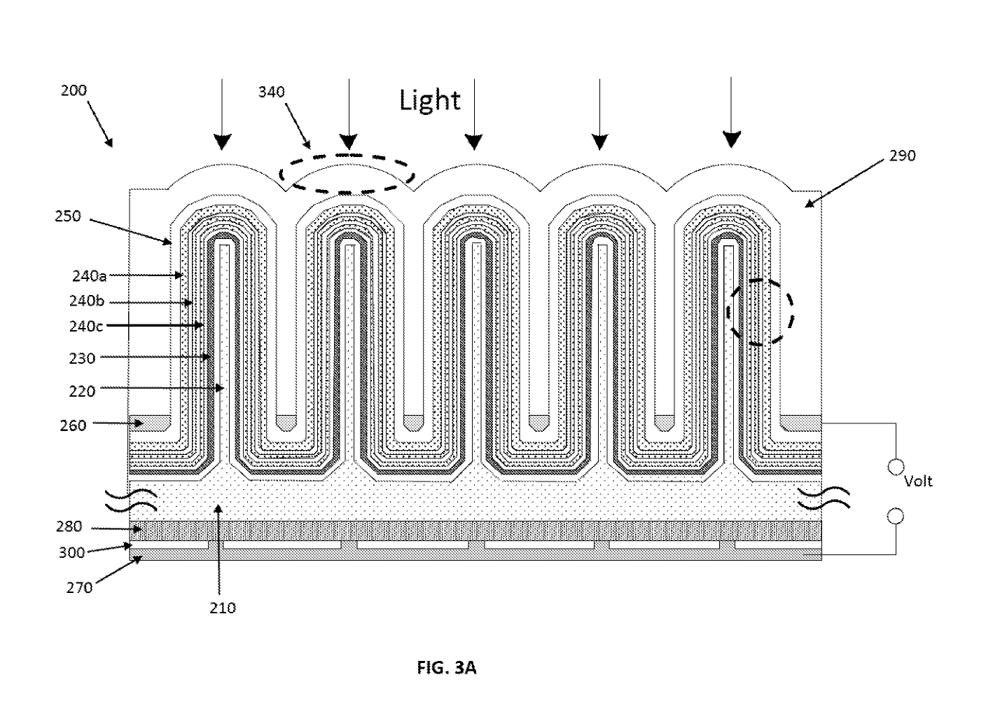

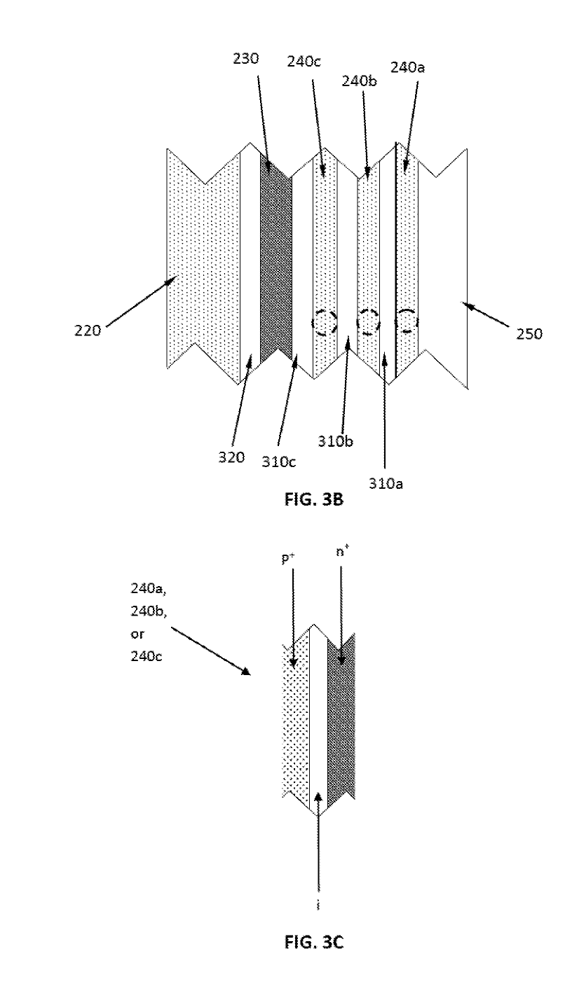

FIG. 3A shows a schematic cross-section of a co-axial quadruple junction pillar structured photovoltaic device 200, according to an embodiment. FIG. 3B shows details of the device 200 in the dotted circle. FIG. 3C shows details of the junction 240c, 240b, or 240a in the dotted circle, wherein the p-i-n junction may consist of three layers, i.e., p+, intrinsic, and n+ layer. The photovoltaic device 200 comprises a substrate 210, one or more structures 220 essentially perpendicular to the substrate 210. An intrinsic layer 320 is disposed on the structures 220. A first doped layer 230 is disposed on the intrinsic layer 320 forming a first junction with the structures 220. A second junction 240c is conformally disposed on the first doped layer 230. A transparent inter layer 310c is conformally disposed between the first doped layer 230 and the first junction 240c. A third junction 240b is conformally disposed on the first junction 230c. A transparent inter layer 310b is conformally disposed between the second junction 240b and the second junction 310c. A fourth junction 240a is conformally disposed on the third junction 230b. A transparent inter layer 310a is conformally disposed between the fourth junction 240a and the third junction 240b. A cladding layer 250 is conformally disposed on the third junction 240a, which is the outermost junction in this example. An electrically conductive material 260 is disposed on the bottom wall of the area between the structures 220. The side walls of the structures 220 are essentially free of the electrically conductive material 260. The electrically conductive material 260 is functional to reflect light incident thereon to the structures 220 and is functional as an electrode of the photovoltaic device 200. Space between the structures 220 is filled with a filler material 290. A second doped layer 280 is disposed on a surface of the substrate 210 opposite to the surface comprising the one or more structures 220. A passivation layer 300 is disposed on the second doped layer and comprises openings whereby the metal layer 270 can create localized contacts through the openings in the passivation layer 300 to the second doped layer 280. The metal layer 270 is functional as an electrode of the photovoltaic device 200. FIG. 1A shows a schematic cross-section of a co-axial double junction pillar structured photovoltaic device 180. FIG. 2A shows a schematic cross-section of a co-axial triple junction pillar structured photovoltaic device 170.

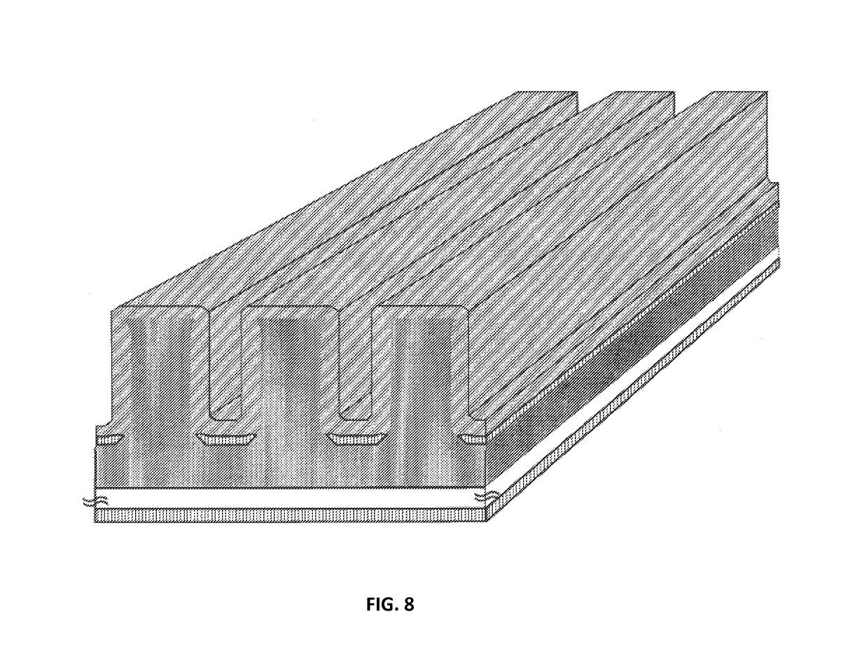

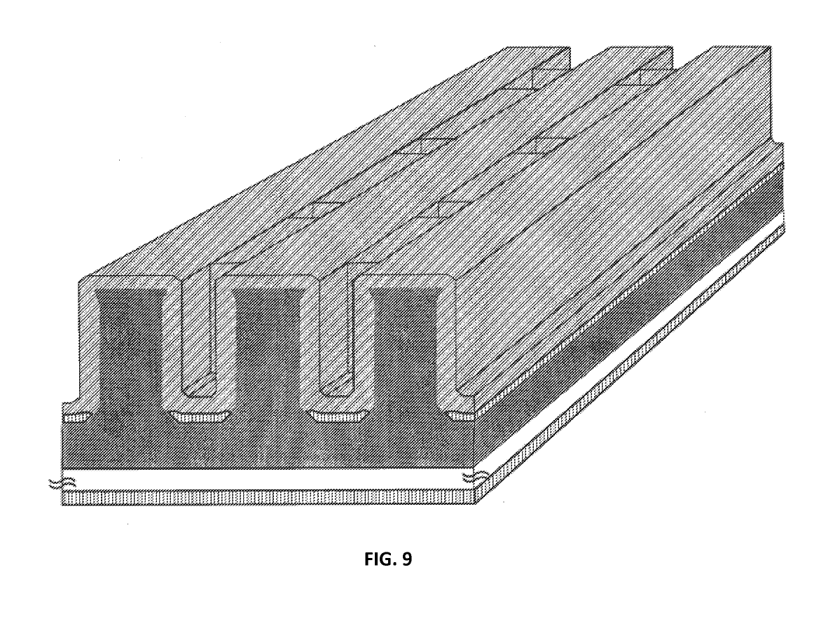

The structures 220 can have any cross-sectional shape. For example, the structures 220 can be cylinders or prisms with elliptical, circular, rectangular, polygonal cross-sections. The structures 220 can also be frusta, cones and/or pyramids. The structures 220 can also be strips as shown in FIG. 8, or a mesh as shown in FIG. 9.

In one embodiment, the structures 220 are pillars arranged in an array, such as a rectangular array, a hexagonal array, a square array, concentric ring.

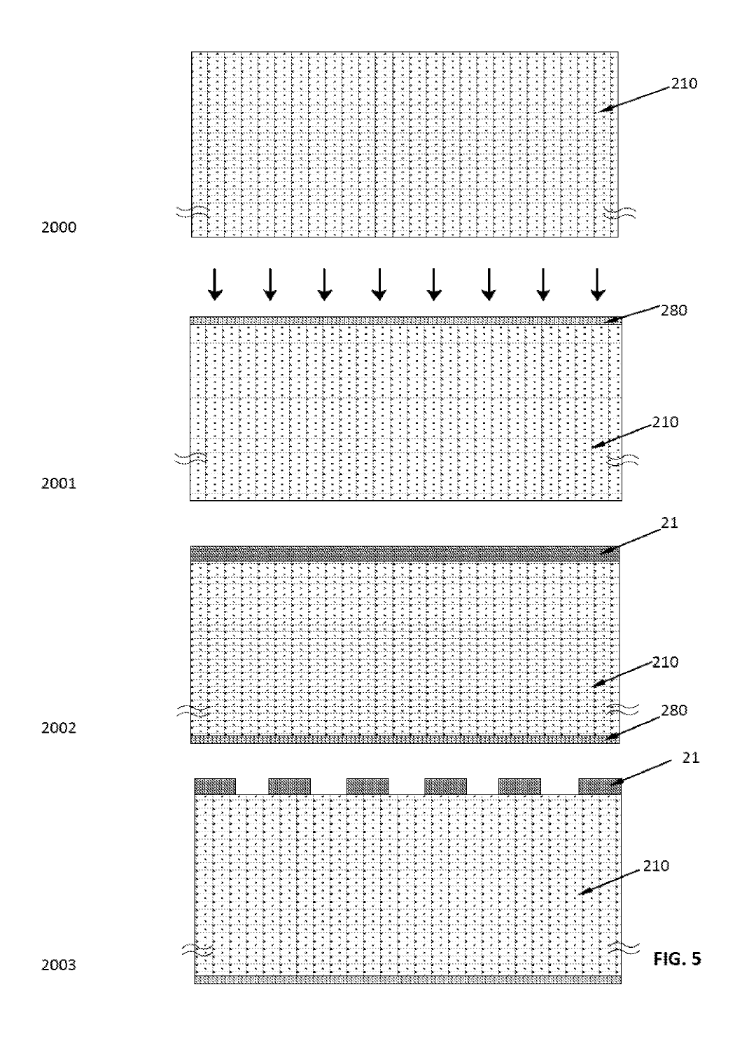

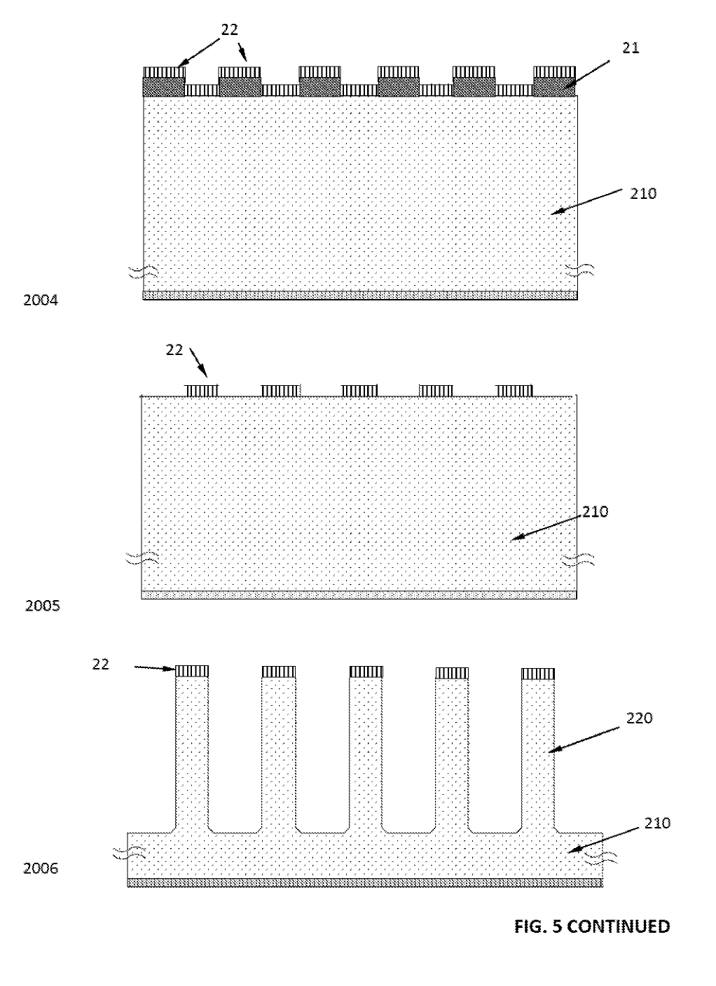

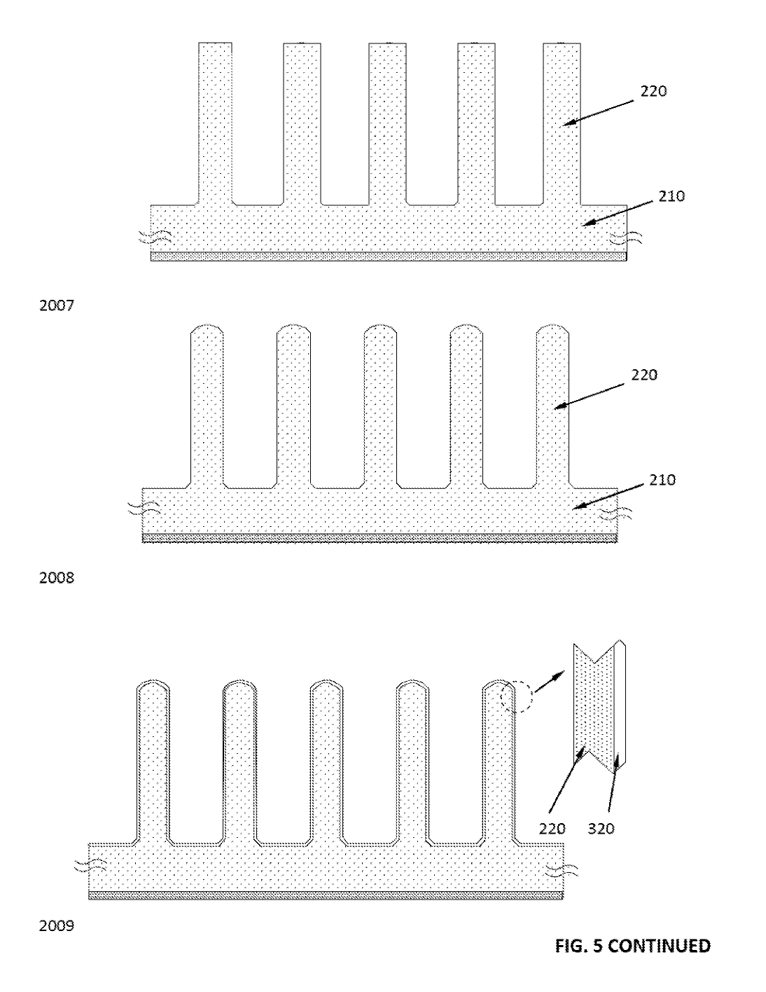

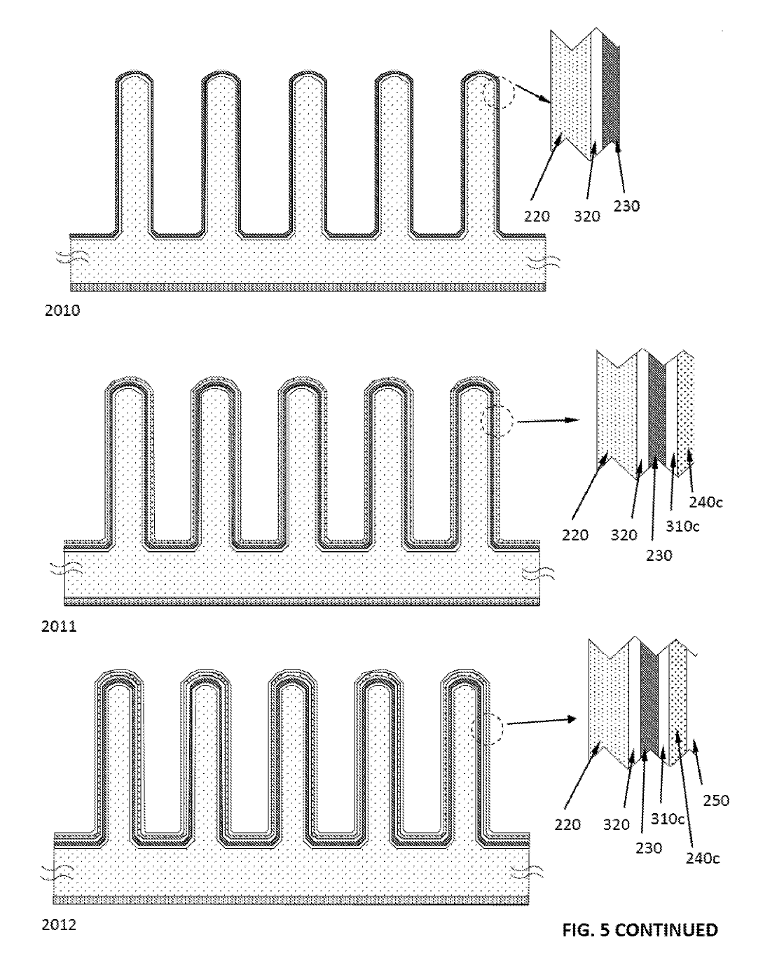

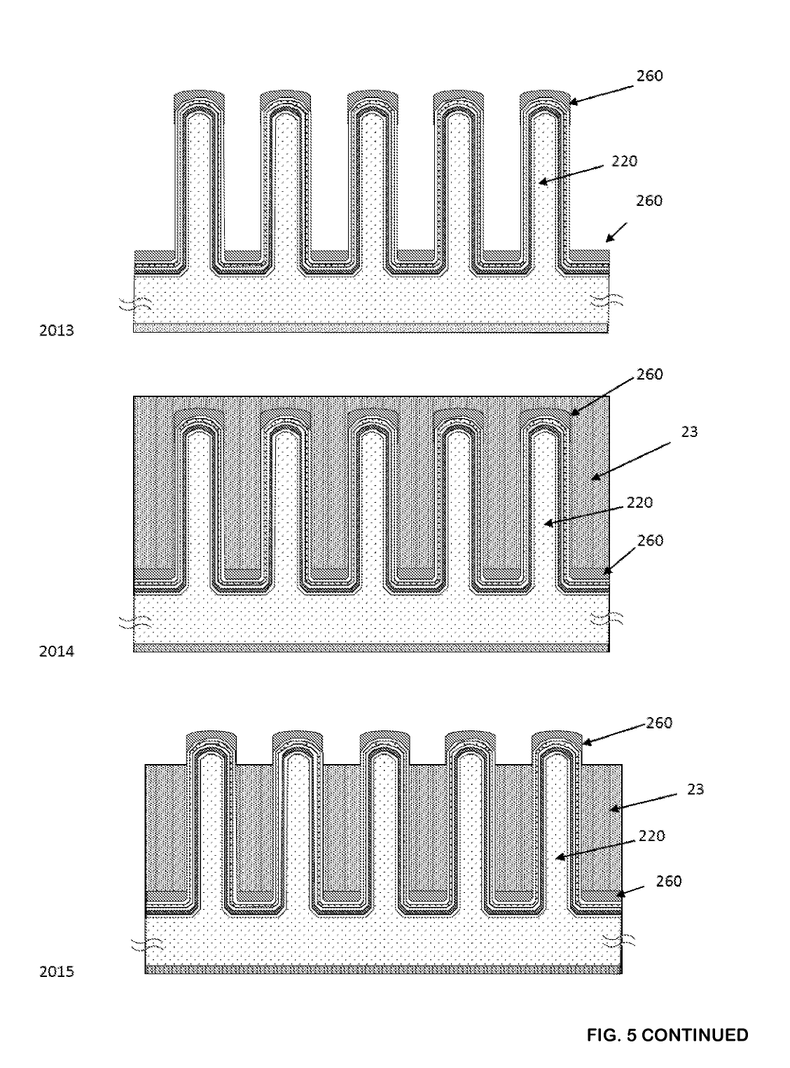

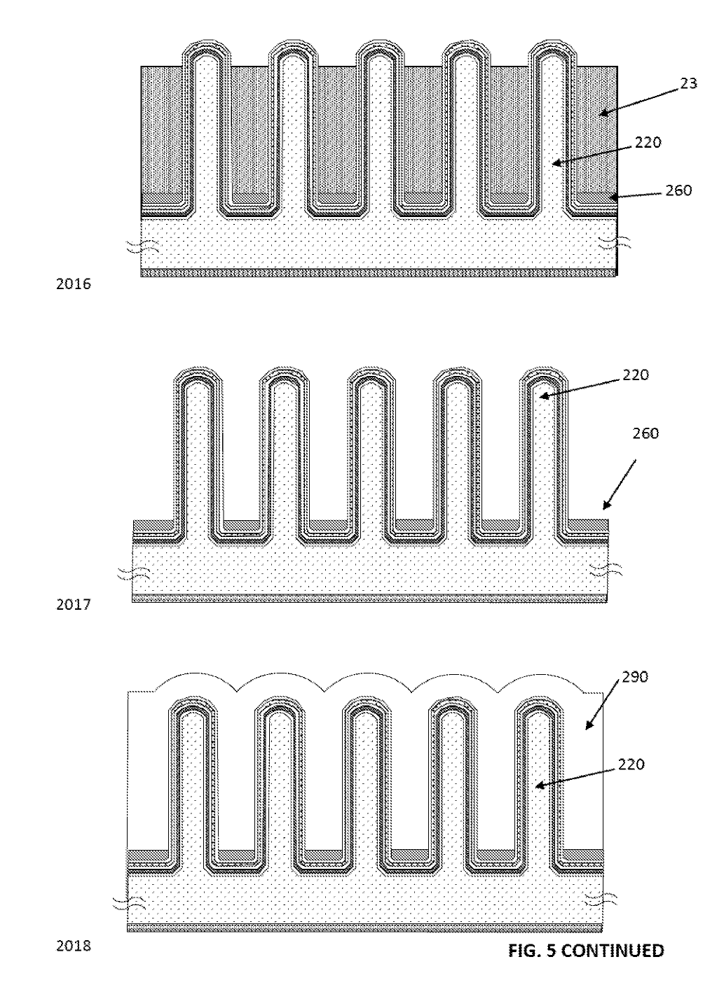

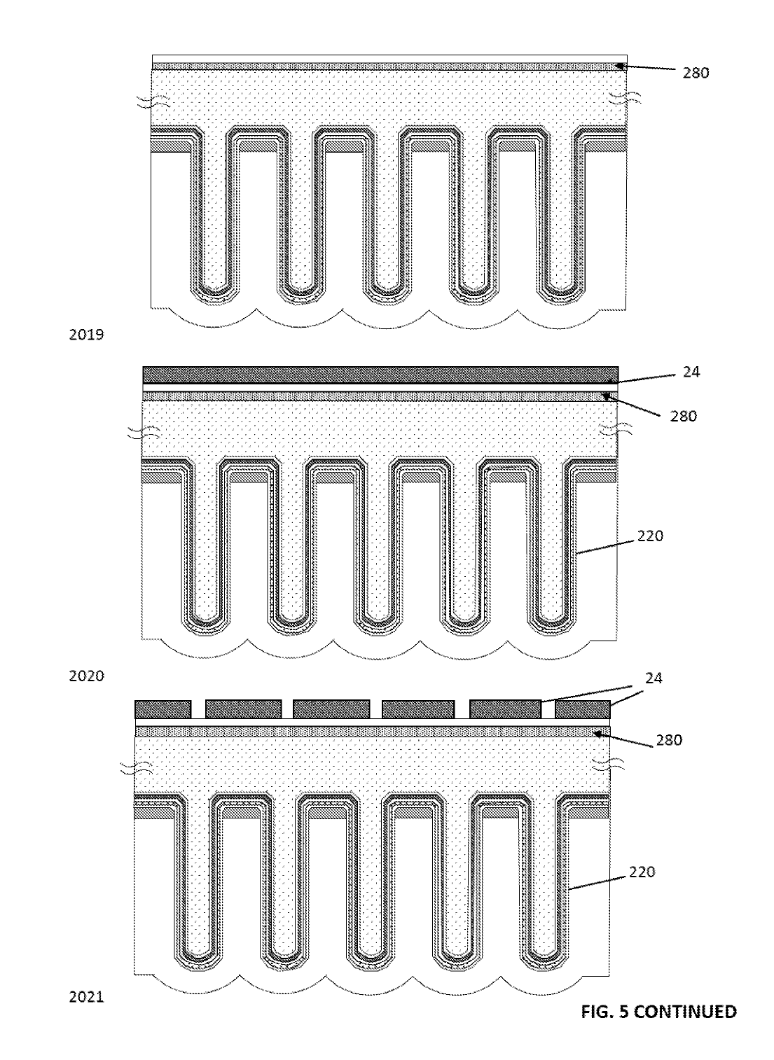

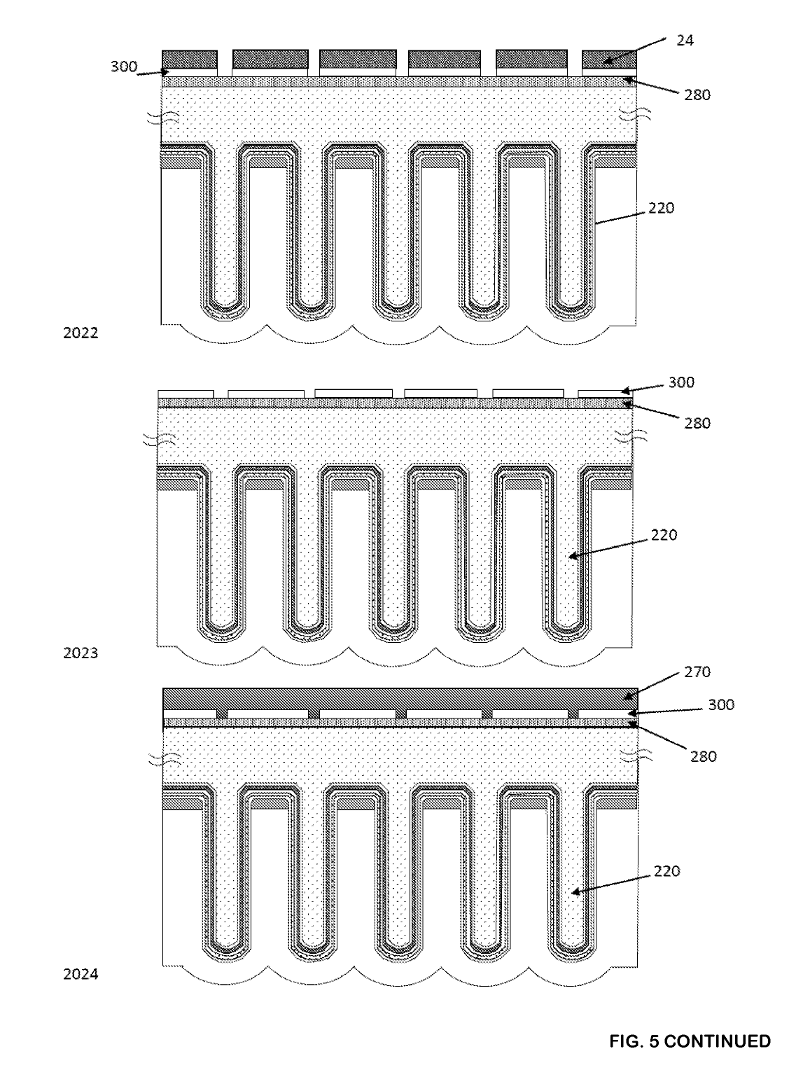

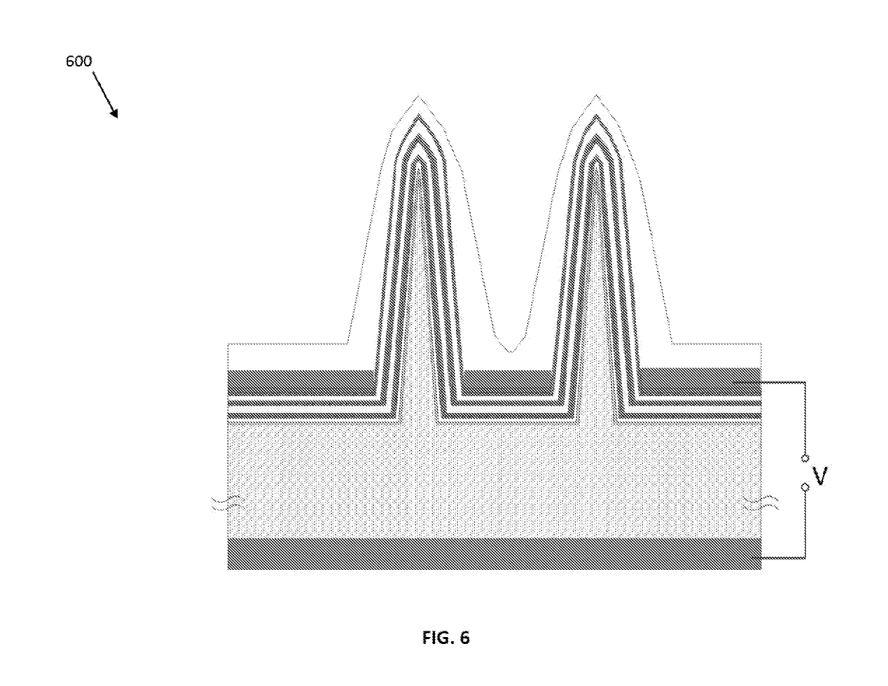

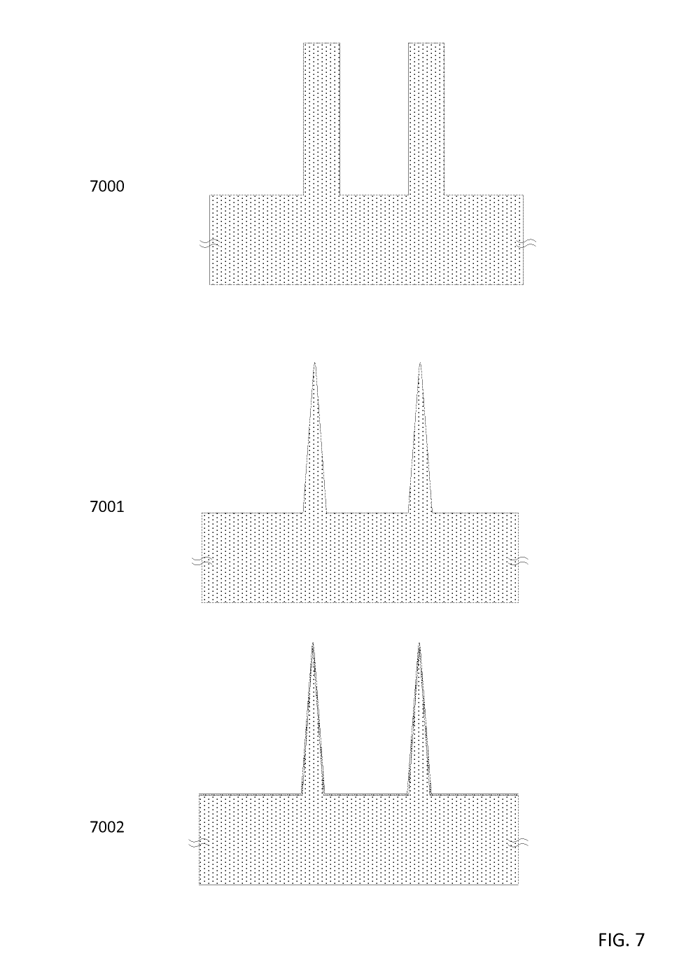

A method of making the FIG. 1A photovoltaic device 180 as shown in FIG. 5, according to an embodiment, comprises the following steps:

In step 2000, the substrate 210 is provided.

In step 2001, a highly doped layer 280 is formed by using an ion implantation and a post annealing process, or thermal diffusion process. If the substrate 210 is p-type, p-type dopant is applied or n-type dopant is applied if the substrate is n-type.

In step 2002, a resist layer 21 is applied to the substrate 210. The resist layer 21 can be applied by spin coating. The resist layer 21E can be a photo resist or an e-beam resist.

In step 2003, lithography is performed. The resist layer 21 now has a pattern of openings in which the substrate 210 is exposed. The resolution of the lithography is limited by the wavelength of the radiation used. Photolithography tools using deep ultraviolet (DUV) light with wavelengths of approximately 248 and 193 nm, allows minimum feature sizes down to about 50 nm. E-beam lithography tools using electron energy of 1 keV to 50 keV allows minimum feature sizes down to a few nanometers.

In step 2004, a mask layer 22 is deposited over the remaining portion of the resist layer 21 and the exposed portion of the substrate 210. The mask layer 22 can be deposited using any suitable method such as thermal evaporation, e-beam evaporation, or sputtering. The mask layer 22 can be a metal such as Cr or Al, or a dielectric such as SiO₂ or Si₃N₄. The thickness of the mask layer 22 can be determined by a height of the structures 220 and etching selectivity (i.e., ratio of etching rates of the mask layer 22 and the substrate 210).

In step 2005, remainder of the resist layer 21 is lifted off by a suitable solvent or ashed in a resist asher.

In step 2006, the exposed portion of the substrate 210 is etched, for example by the Bosch Process, to a desired depth to form the structures 220.

In step 2007, the mask layer 22 is removed by a suitable method such as wet etching with suitable etchant, ion milling, sputtering.

In step 2008, a top portion of the structures 220 is rounded or tapered using a suitable technique such as dry etch or wet etch.

In step 2009, the intrinsic layer 320 is conformally deposited on the structures 220.

In step 2010, the first doped layer 230 is conformally deposed onto the intrinsic layer 320 using a suitable isotropic deposition method such as chemical vapor deposition or plasma enhanced chemical vapor deposition.

In step 2011 the transparent inter layer 310c is conformally (i.e., isotropically) deposited on the amorphous silicon layer 230. The transparent electrically conductive material 310c can be deposited by a suitable technique such as plating, chemical vapor deposition or atomic layer deposition. The junction 240c is conformally deposited on the transparent inter layer 310c. This step is repeated once to produce a double junction shown in FIG. 1A, twice to produce a triple junction shown in FIG. 2A, and three times to produce a quadruple junction shown in FIG. 3A.

In step 2012, the cladding layer 250 is conformally deposited on the outermost (i.e., the junction that is among those junctions conformally disposed on the structures and is not between another junction and the structures) deposed junction 240c, 240b, or 240a.

In step 2013, the electrically conductive material 260 is deposited between the structures 220 and on top of the tapered structures 220. This step may be carried out using a conventional lithography technique.

In step 2014, a sacrificial material such as a resist 23 is deposited to cover the structures 220 and the deposited electrically conductive material 260 at the top of the structures 220.

In step 2015, a top portion of the resist 23 is removed, for example by oxygen plasma etching. The electrically conductive material 260 on the top of the structures 220 is exposed and the electrically conductive material 260 between the structures 220 is not exposed.

In step 2016, the electrically conductive material 260 on the top of the structures 220 is removed by any suitable method such as wet etching.

In step 2017, the sacrificial material 23 is removed.

In step 2018, the filler material 290 is deposited in space between the structures 220 and microlenses 340 are formed on the top surface of the filler material 290.

In step 2019, a passivation layer 300 is deposited onto the second doped layer 280 using a suitable method such as atomic layer deposition, chemical vapor deposition, or thermal deposition. The layer 300 is an oxide material such as SiO₂, HfO₂, Al₂O₃.

In step 2020, a photo resist 24 is deposited onto the oxide layer 300.

In step 2021, lithography is performed. The resist layer 301 now has a pattern of openings in which the second doped layer 280 is exposed.

In step 2022, the passivation layer 300 exposed by the photoresist pattern is etched by an etchant or dry etch to have openings.

In step 2023, the remaining photoresist material 24 is removed and the substrate is cleaned.

In step 2024, a metal layer 270 is deposited using a suitable method such as sputtering, e-beam evaporation, or a thermal evaporation process to create localized contact points between the metal layer and the second doped layer.

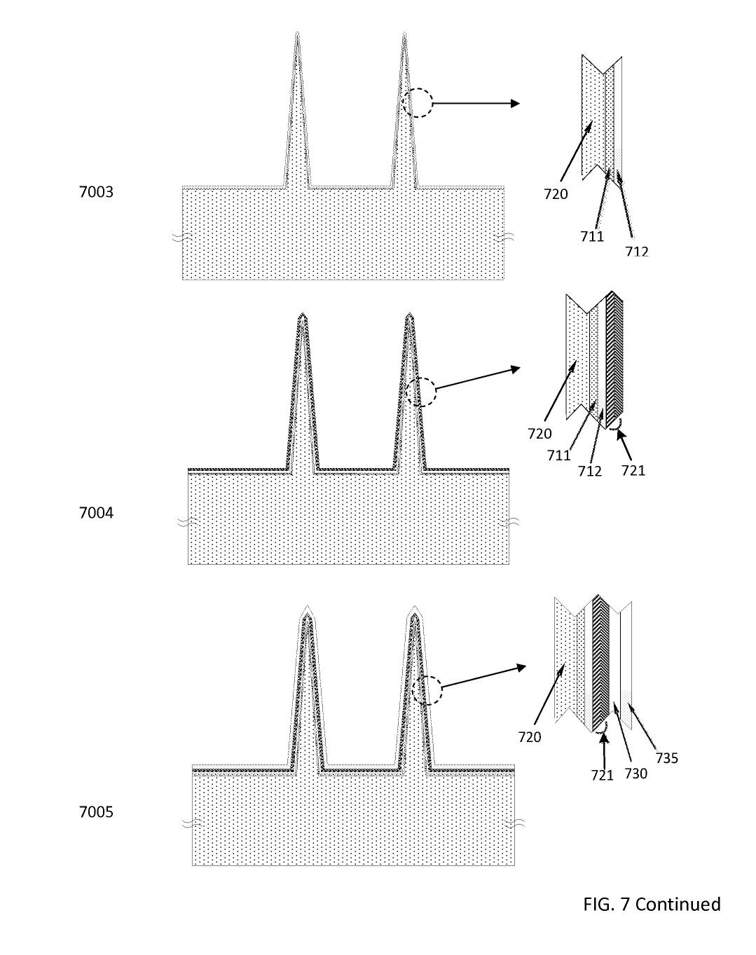

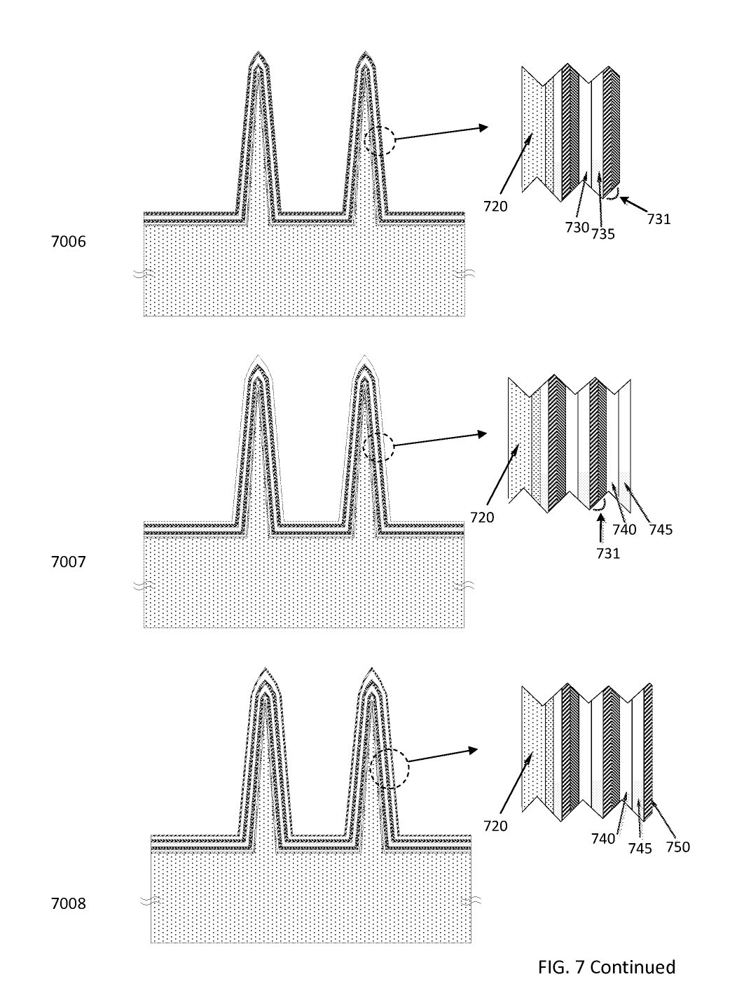

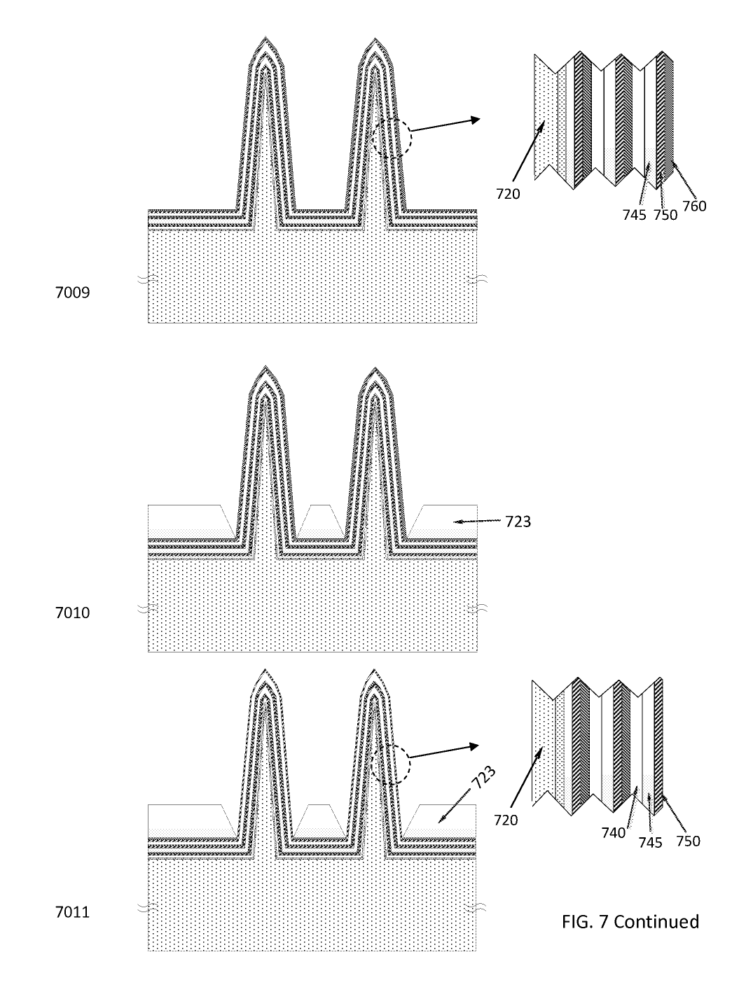

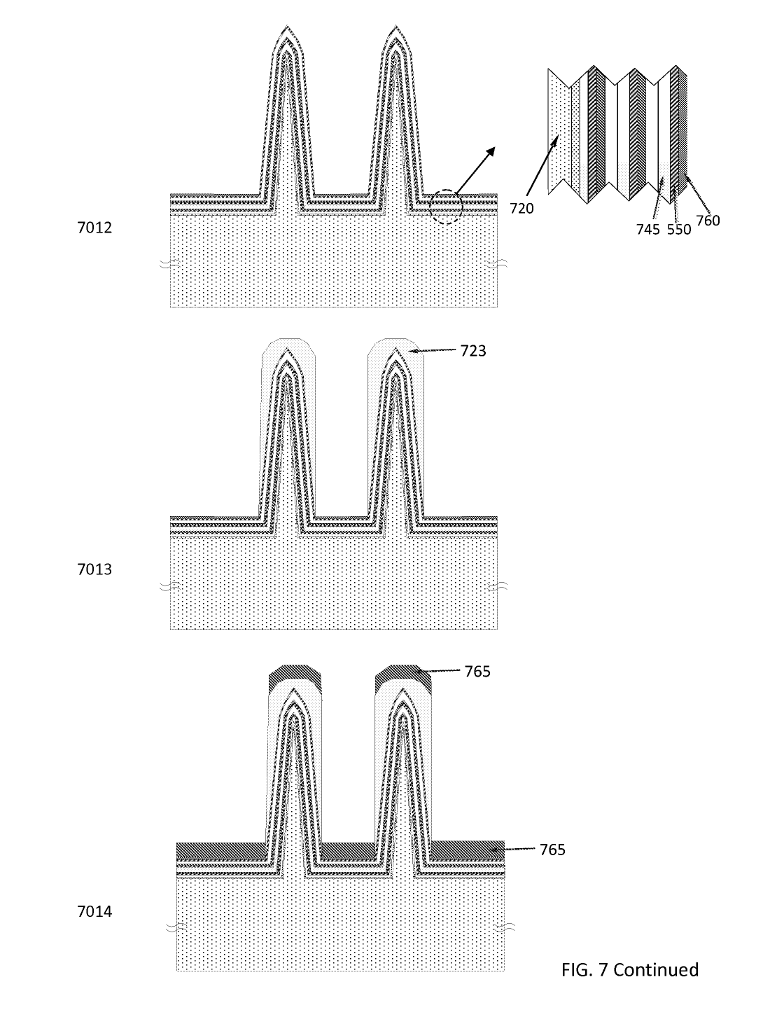

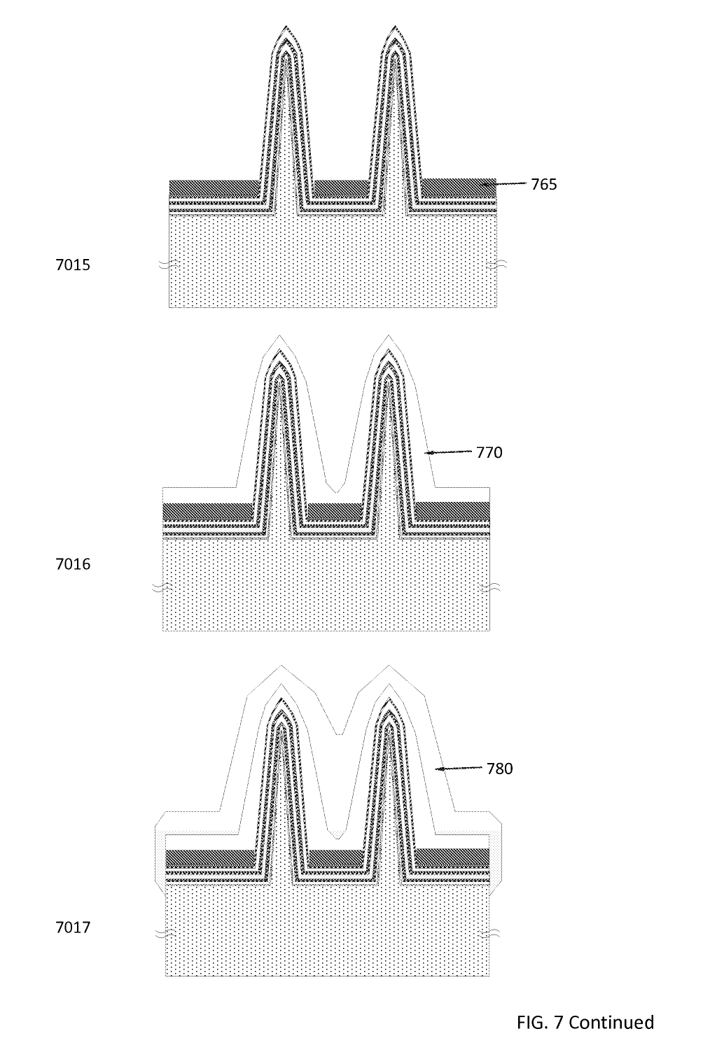

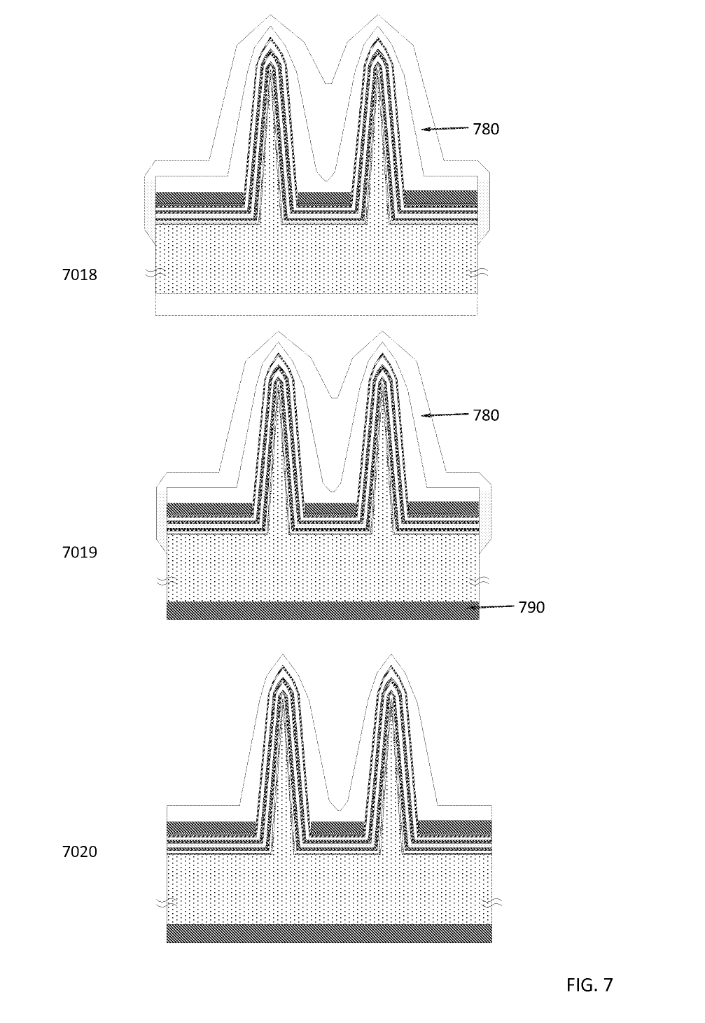

FIG. 6 shows a schematic cross-section of a co-axial triple junction tapered pillar structured photovoltaic device 600, according to an embodiment. FIG. 7 shows details of the structure of the device 600 and a method of fabrication of device 600.

In step 7000, a substrate 710 is processed using the same lithography steps and etch process introduced in steps 2000-2007 in FIG. 5.

In step 7001, structures 720 is tapered using a suitable technique such as wet etch.

In step 7002, the structures 720 are conformally doped by thermal diffusion process to have a high doping concentration on the surface.

In step 7003, a nucleation layer 711 and buffer layer 712 are disposed over the structures 720. In an embodiment, GaAs or InGaAs is disposed as the nucleation/buffer layer by MOCVD (metalorganic chemical vapor deposition) or MBE (molecular beam epitaxy) technique.

In step 7004, a pair of n+/p+ layer or p+/n+ layer 721 of compound semiconductor materials is disposed by MOCVD or MBE. Here, the p+ and the n+ can have be a different material each other. This n+/p+ or p+/n+ pair is called a tunnel junction because it is electrically short connection through Zener tunneling effect and it serves as a heterojunction interface between two p-n diodes having different energy bandgap materials.

In step 7005, the second junction layers 730/735 are disposed using the compound semiconductor material as shown in Table 1 by MOCVD or MBE. In one embodiment, the layer 730 is doped with a p-type dopant while the layer 735 is doped with an n-type dopant.

In step 7006, another n+/p+ or p+/n+ tunnel junction layer 731 is disposed.

In step 7007, the third junction layers 740/745 are disposed using the compound semiconductor material as shown in Table 1 by MOCVD or MBE. In one embodiment, the layer 740 is doped with a p-type dopant while the layer 745 is doped with an n-type dopant.

In step 7008, the layer 750 using a wide bandgap material is disposed by MOCVD or MBE so that a heterojunction between 750 and layer 745 can form a built-in electric field toward the core direction, resulting in reduced surface recombination. This wide bandgap layer providing the front surface field is called a window layer. In an embodiment, a highly doped AlInP is used.

In step 7009, the highly doped layer 760 is disposed on the 750 by MOCVD or MBE. This layer is supposed to have a good ohmic contact with the top electrode. In an embodiment, a highly doped GaAs is used.

In step 7010, a thin layer of a sacrificial material such as a resist 723 having a low viscosity is deposited using the spin coat method to cover the recessed portion of the structures 720. Due to a surface force, the sacrificial layer pulls back near the boundary with the structures 720.

In step 7011, portion of the layer 760 not covered by resist 723 is removed by wet etch.

In step 7012, resist 723 is removed using any suitable method such as dissolution by an etchant or solvent.

In step 7013, a sacrificial material such as a resist 723 is deposited by dipping the pillar part of the structures 720 into the liquid form of photoresist while holding the substrate in an upside down position, after which it should be cured in that position.

In step 7014, the electrically conductive material 765 is deposited between the structures 720 and on top of the structures 720. This step may be carried out using a suitable method such as sputtering, a hermal evaporation, or an e-beam evaporation process.

In step 7015, a top portion of the conductive layers 765 is lifted off by a suitable solvent, and remaining photoresists is removed in a resist asher.

In step 7016, the cladding layer 770 is conformally deposited on the outermost layer of the structures 720.

In step 7017, a polymer material or a wax 780 is deposited on the top surface of the structures 720 using any suitable method such as a spin coating or a dipping half way into the material. This is to protect the structures 720 from wet etching process in following step.

In step 7018, a few micron meters of the substrate 710 is removed by a wet etch on the rear surface and cleaned thoroughly. The purpose of removing part of the back surface is to remove the defects caused during the fabrication processes and to make a clean contact with a conductive layer for the electrode.

In step 7019, a metal layer 790 is deposited using a suitable method such as sputtering, e-beam evaporation, or a thermal evaporation process.

In step 7020, the protection material 780 is removed by a suitable solvent.

A method of converting light to electricity comprises: exposing the photovoltaic device 170, 180, 200, 330 to light; absorbing the light and converting the light to electricity using the structures 220; drawing an electrical current from the photovoltaic device 170, 180, 200, 330. As shown in FIGS. 1A, 2A, 3A and 4, the electrical current can be drawn from the electrically conductive material 260 and the metal layer 270.

A photo detector according to an embodiment comprises the photovoltaic device 170, 180, 200, 330, wherein the photo detector is configured to output an electrical signal when exposed to light.

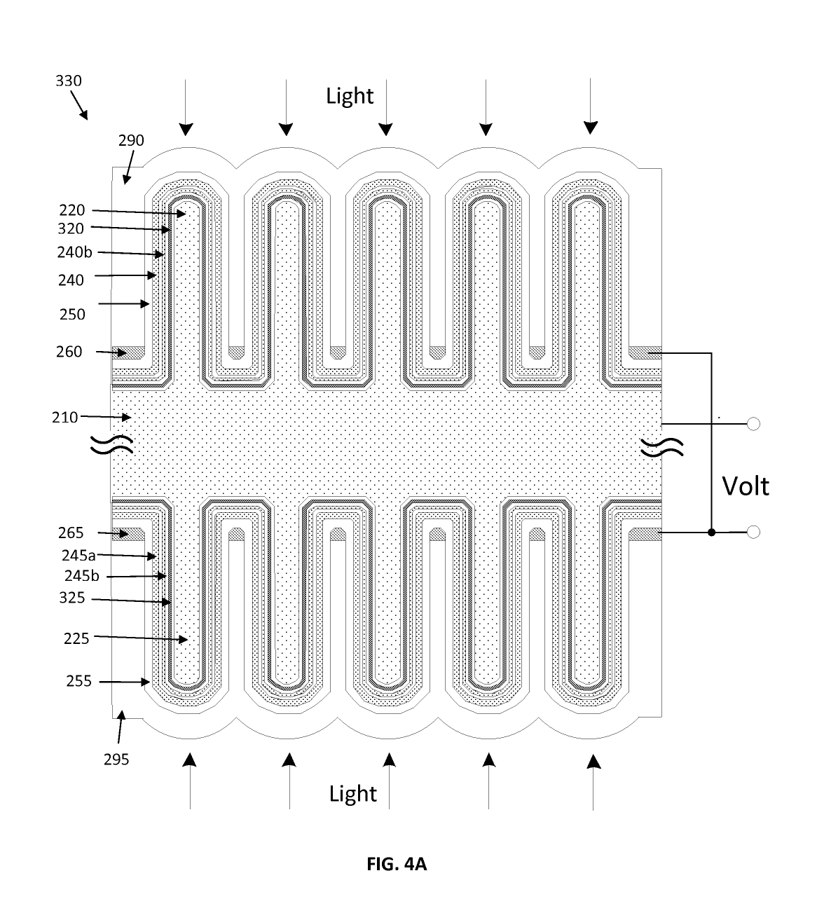

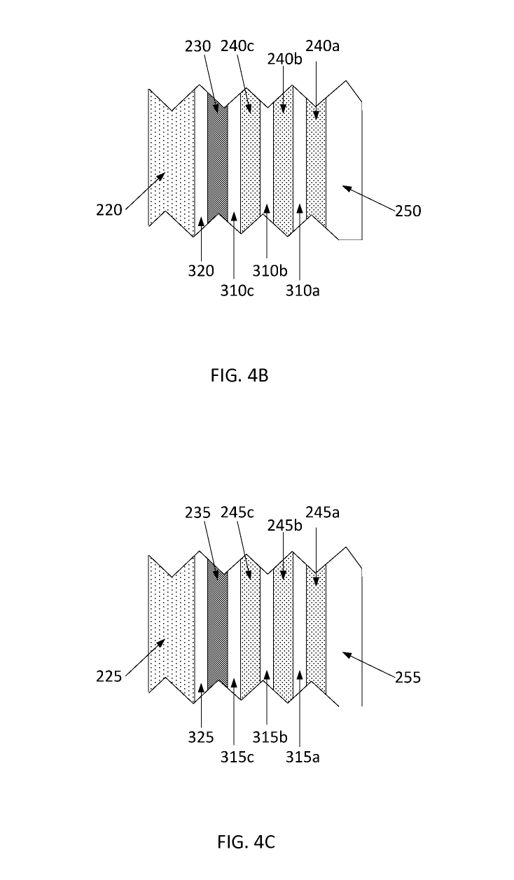

FIGS. 4A-4C show a schematic cross-section of a bifacial pillar structured photovoltaic device 330, according to an embodiment. In an embodiment, a first structure of one or more structures 220 and a second structure of one or more structures 220 are on opposite faces of the substrate 210. The photovoltaic device 330 comprises a substrate 210 and a first structure of one or more structures 220 essentially perpendicular to the substrate 210. An intrinsic layer 320 is disposed on the structures 220. A first doped layer 230 is disposed on the intrinsic layer 320 forming a first junction with the structures 220. A second junction 240c is conformally disposed on the first doped layer 230. A transparent inter layer 310c is conformally disposed between the first doped layer 230 and the first junction 240c. A third junction 240b is conformally disposed on the first junction 230c. A transparent inter layer 310b is conformally disposed between the second junction 240b and the second junction 310c. A fourth junction 240a is conformally disposed on the third junction 230b. A transparent inter layer 310a is conformally disposed between the fourth junction 240a and the third junction 240b. A cladding layer 250 is conformally disposed on the third junction 230a, which is the outermost junction in this example. An electrically conductive material 260 is disposed on the bottom wall of the area between the structures 220. The side walls of the structures 220 are essentially free of the electrically conductive material 260. The electrically conductive material 260 is functional to reflect light incident thereon to the structures 220 and is functional as an electrode of the photovoltaic device 330. Space between the structures 220 is filled with a filler material 290. The photovoltaic device 330 also comprises a second structure of one or more structures 225 essentially perpendicular to the substrate 210, on a face of the substrate 210 opposite to the first structure of one or more structures 220. An intrinsic layer 325 is disposed on the structures 225. A first doped layer 235 is disposed on the intrinsic layer 325 forming a first junction with the structures 225. A second junction 245c is conformally disposed on the first doped layer 235. A transparent inter layer 315c is conformally disposed between the first doped layer 235 and the first junction 245c. A third junction 245b is conformally disposed on the first junction 235c. A transparent inter layer 315b is conformally disposed between the second junction 245b and the second junction 315c. A fourth junction 245a is conformally disposed on the third junction 235b. A transparent inter layer 315a is conformally disposed between the fourth junction 245a and the third junction 245b. A cladding layer 255 is conformally disposed on the third junction 235a, which is the outermost junction in this example. An electrically conductive material 265 is disposed on the bottom wall of the area between the structures 225. The side walls of the structures 225 are essentially free of the electrically conductive material 265. The electrically conductive material 265 is functional to reflect light incident thereon to the structures 225 and is functional as an electrode of the photovoltaic device 330. Space between the structures 225 is filled with a filler material 295. The substrate 210 may comprise an electrically conductive material in the substrate 210. The number of junctions and composition of layers on the first structure of one or more structures 220 does not have to be identical to the number of junctions and composition of layers on the second structure of one or more structures 225.

A method of detecting light comprises: exposing the photovoltaic device 170, 180, 200, 330 to light; measuring an electrical signal from the photovoltaic device 170, 180, 200, 330. The electrical signal can be an electrical current, an electrical voltage, an electrical conductance and/or an electrical resistance. A bias voltage can be applied to the structures 220 in the photovoltaic device 170, 180, 200, 330 when measuring the electrical signal.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A device, comprising: a substrate comprising a semiconductor material having a first side and a second side, one or more structures essentially perpendicular to the first side of the substrate, one or more layers conformally disposed on the one or more structures wherein the one or more structures and the one or more layers form one or more junctions, and an electrically conductive material disposed on the first side of the substrate in an area between the one or more structures.

2. The device of claim 1, wherein the device comprises a photovoltaic device operable to convert light to electricity.

3. The device of claim 1, wherein the electrically conductive material comprises an electrically conductive layer.

4. The device of claim 1, wherein the one or more structures have one or more sidewalls that are essentially free of the electrically conductive material.

5. The device of claim 1, wherein the one or more junctions comprises at least two junctions.

6. The device of claim 5, wherein the two or more junctions are not separated by a tunnel junction.

7. The device of claim 5, wherein the two or more junctions are electrically connected in series.

8. The device of claim 1, wherein the one or more junctions are selected from a group consisting of a p-i-n junction, a p-n junction, a heterojunction, and a combination thereof.

9. The device of claim 1, wherein the one or more layers comprises a heavily doped p type semiconductor material layer and a heavily doped n type semiconductor material layer, and optionally an intrinsic semiconductor layer sandwiched between the heavily doped p type semiconductor material layer and the heavily doped n type semiconductor material layer.

10. The device of claim 1, wherein the one or more layers comprises a microcrystalline semiconductor material.

11. The device of claim 1, wherein the one or more layers comprises a semiconductor material selected from a group consisting of silicon, germanium, group III-V compound materials, group II-VI compound materials, and quaternary materials.

12. The device of claim 6, wherein materials forming a first junction of the two or more junctions has a smaller band gap than materials forming a second junction of the two or more junctions, wherein the first junction is sandwiched between the structures and the second junction.

13. The device of claim 1, wherein the substrate is a single crystalline material.

14. The device of claim 1, wherein the one or more structures have the same composition as the substrate; the one or more structures are cylinders, prisms, cones, frusta and/or pyramids; and/or the one or more structures have a cross-section selected from a group consisting of elliptical, circular, rectangular, and polygonal cross-sections, strips, or a mesh.

15. The device of claim 1, wherein a top portion of the structure is rounded or tapered.

16. The device of claim 5, further comprising an inter layer sandwiched between a pair of neighboring junctions of the one or more junctions.

17. The device of claim 16, wherein the inter layer is made of an electrically transparent conductive oxide material selected from a group consisting of ITO (indium tin oxide), AZO (aluminum doped zinc oxide), ZIO (zinc indium oxide), ZTO (zinc tin oxide), and a combination thereof.

18. The device of claim 1, further comprising a cladding layer disposed on the one or more structures.

19. The device of claim 18, wherein the cladding layer is substantially transparent to visible light with a transmittance of at least 50%; the cladding layer is made of an electrically conductive material; the cladding layer is a transparent conductive oxide; the cladding layer is made of a material selected from a group consisting of ITO (indium tin oxide), AZO (aluminum doped zinc oxide), ZIO (zinc indium oxide), ZTO (zinc tin oxide), Si₃N₄, Al₂O₃, HfO₂, and a combination thereof.

20. The device of claim 18, wherein the cladding layer is configured as an electrode of the device.

21. The device of claim 1, wherein the electrically conductive material is made of a material selected from a group consisting of Al, Ti, Ni, Cr, Cu, Ag, Pd, Pt, and a combination thereof.

22. The device of claim 21, wherein the electrically conductive material is an electrode of the device.

23. The device of claim 1, further comprising a second doped layer on a surface of the substrate, wherein the second doped layer is disposed on the surface opposite to the surface comprising the one or more structures.

24. The device of claim 1, further comprising a passivation layer on the second doped layer, wherein the passivation layer is configured to passivate the second doped layer.

25. The device of claim 24, wherein the passivation layer comprises openings in the passivation layer; the passivation layer is made of an oxide material selected from a group consisting of Al₂O₃, HfO₂, SiO₂, and a combination thereof.

26. The device of claim 1, further comprising a metal layer disposed on the passivation layer and in the openings of the passivation layer, creating localized contact between the metal layer and the second doped layer.

27. The device of claim 26, wherein the metal layer is made of material selected from a group consisting of Al, Tl, Cr, Cu, Ag, Pd, Pt, and a combination thereof.

28. The device of claim 27, wherein the metal layer is an electrode of the device.

29. The device of claim 1, wherein a first structure of one or more structures and a second structure of one or more structures are on opposite sides of the substrate.

30. A method of making a device, comprising forming a substrate having a first side and a second side, forming one or more structures essentially perpendicular to the first side of the substrate, forming one or more layers conformally disposed on the one or more structures, wherein the one or more structures and the one or more layers form one or more junctions, and forming an electrically conductive material disposed on the first side of the substrate in an area between the one or more structures

31. The method of claim 30, wherein the forming the electrically conductive material comprises disposing the electrically conductive material on the one or more junctions.

32. The method of claim 30, further comprising: generating a pattern of openings in a resist layer using a lithography technique, wherein locations and shapes of the openings correspond to location and shapes of the structures; forming the structures by etching the substrate; and depositing the mirror layer to the substrate.

33. The method of claim 30, further comprising tapering or rounding a top portion of the structures.

34. The method of claim 30, wherein the structures are formed by deep etch.

35. A method of converting light to electricity comprising: exposing a device to light, wherein the device comprises a semiconductor material having a first side and a second side, one or more structures essentially perpendicular to the first side of the semiconductor material, two or more junctions conformally disposed on the one or more structures, and an electrically conductive material disposed on the first side of the semiconductor material, wherein the electrically conductive material is configured to conduct electricity generated by the one or more junctions; and drawing an electrical current from the device.

36. A photo detector comprising the device of claim 1, wherein the photo detector is configured to output an electrical signal when exposed to light.

37. A method of detecting light comprises: exposing the device of claim 1 to light; measuring an electrical signal from the device.

38. The method of claim 37, wherein the electrical signal is an electrical current, an electrical voltage, an electrical conductance and/or an electrical resistance.

39. The method of claim 37, wherein a bias voltage is applied to the structures in the device.
